(19) United States
(12) Patent Application Publication
(10) Pub. No.: US 2006/0132153 A1
(43) Pub. Date: Jun. 22, 2006

(54) Assembly with a detachable member

(75) Inventor: John K. Gritters, Livermore, CA (US)

Correspondence Address: N. KENNETH BURRASTON;KIRTON & MCCONKIE, P.O. BOX 45120, SALT LAKE CITY, UT, 84145-0120, US

(73) Assignee: FormFactor, Inc.

(21) Appl. No.: 11/021,412

(22) Filed: Dec. 22, 2004

(51) Int. Cl. G01R 31/02

(52) U.S. Cl. 324/754

(57) ABSTRACT

A structure is fabricated in a generally two-dimensional orientation. The structure includes a detachable member or members. The structure is assembled into a three-dimensional orientation. The detachable member or members are attached to another object and released from the structure.

### BACKGROUND

The present invention relates to systems and methods for providing an assembly with a detachable member.

An assembly or structure may be created in two dimensions and then assembled or erected into a three dimensional configuration. It may be, for example, more efficient or less labor intensive to construct components in a two dimensional environment because it may be easier to work on generally flats object than erect objects.

Single-step assemblies are assemblies that are assembled or erected in a single step. Perhaps the best recognized single-step assembly is a pop-up in children's books in which the action of turning a page automatically causes a two dimensional object to erect into a three dimensional structure. In this example, all of the objects are printed two-dimensionally and positioned on the page such that they are all interconnected in a particular manner. Numerous interconnection schemes can be used to allow one or more structures to erect with a single step. This type of single-step construction scheme may be applied to other types of applications. For example, single-step microstructure assemblies involve small structures that are manufactured using traditional semiconductor layering processes. Single-step microstructures can be manufactured on a silicon wafer or substrate and then later erected into a three dimensional structure. Such microstructures have been used to create semiconductor heat shields and optical switches.

Semiconductor dies are typically produced by creating several identical devices on a semiconductor wafer, using known techniques of photolithography, deposition, and the like. Generally, these processes are intended to create a plurality of fully-functional integrated circuit devices, prior to singulating (severing) the individual dies from the semiconductor wafer. In practice, however, certain physical defects in the wafer itself and certain defects in the processing of the wafer inevitably lead to some of the dies being “good” (fully-functional) and some of the dies being “bad” (non-functional). It is generally desirable to be able to identify which of the plurality of dies on a wafer are good dies prior to their packaging, and preferably prior to their being singulated from the wafer. To this end, a wafer “tester” or “prober” may advantageously be employed to make a plurality of discrete pressure connections to a like plurality of discrete connection pads (bond pads) on the dies. In this manner, the semiconductor dies can be tested and exercised prior to singulating the dies from the wafer. A conventional component of a wafer tester is a probe card to which a plurality of probe elements make temporary connections to respective bond pads of the semiconductor dies and test signals are passed to and from the dies via the probes.

In constructing the probes of a probe card, a plurality of probes are mounted to the probe card in a particular orientation that is compatible with both the probe card and the dies to be tested. There are also other applications in which a plurality of small structures are assembled and attached to a substrate or other object. Examples of such applications include testing scenarios other than a semiconductor wafer probing described above. Such examples include without limitation any testing, monitoring, burn in, or packaging scenario in which probes are involved. Such testing scenarios may include testing any of a variety of electronic devices, including not only semiconductor wafers but singulated dies (packaged or unpackaged), electronics modules, etc. Other examples in which a plurality of small structures may be assembled into a three-dimensional configuration and attached to a substrate or other object include an array of micro-mirrors, micro-antennae, photosensitive structures, pixel display structures, phosphor dots, or any type of microelectromechanical system (MEMS). There is, therefore, a need for an efficient way to manufacture and assemble arrays of structures.

### SUMMARY

The present invention relates to an assembly with a detachable member. One embodiment of the present invention is a single-step-assembly microstructure with a detachable member. Such a single-step-assembly microstructure may be manufactured in a two-dimensional layering process and then assembled into a three-dimensional structure with a single step. The detachable member may be configured to be detached from the microstructure and coupled to an independent structure. This embodiment allows items to be manufactured two-dimensionally, erected three dimensionally, and then attached to independent objects in the three-dimensional orientation. One application for this embodiment is to attach semiconductor probes to a probe card. Other exemplary applications include without limitation micro-mirrors, micro-antennae, photosensitive structures, pixel display structures, phosphor dots, or any type of microelectromechanical system (MEMS).

### BRIEF DESCRIPTION OF THE DRAWINGS

FIG. 1A illustrates an exemplary single-step-assembly microstructure in accordance with one embodiment of the present invention;

FIGS. 1B and 1C illustrate the primary and secondary members of FIG. 1A;

FIG. 2 illustrates a side view of FIG. 1A;

FIG. 3 illustrates the structure of FIG. 2 lifted into an assembled position.

FIGS. 4A-4C illustrate a portion of an exemplary process for making a single-step-assembly microstructure.

FIGS. 5A-5C illustrate another portion of an exemplary process for making a single-step-assembly microstructure.

FIGS. 6A-6C illustrate another portion of an exemplary process for making a single-step-assembly microstructure.

FIGS. 7A-7C illustrate another portion of an exemplary process for making a single-step-assembly microstructure.

FIGS. 8A-8C illustrate another portion of an exemplary process for making a single-step-assembly microstructure.

FIGS. 9A-9C illustrate another portion of an exemplary process for making a single-step-assembly microstructure.

FIGS. 10A-10C illustrate another portion of an exemplary process for making a single-step-assembly microstructure.

FIGS. 11A-11C illustrate another portion of an exemplary process for making a single-step-assembly microstructure.

FIGS. 12A, 12B, 13A, 13B, and 13C illustrate an exemplary process for making a detachable member.

FIG. 14 illustrates a single-step-assembly microstructure in an assembled position.

FIG. 15 illustrates an exemplary probe card assembly.

FIGS. 16A and 16B illustrate attachment of an exemplary detachable member to a probe substrate.

FIGS. 17A and 17B illustrate attachment of another exemplary detachable member to a probe substrate.

FIGS. 18A and 18B illustrate attachment of yet another exemplary detachable member to a probe substrate.

FIG. 19 illustrates a plurality of detachable members on a single-step-assembly microstructure.

FIG. 20 illustrates a plurality of detachable members on a plurality of single-step-assembly microstructures.

FIGS. 21A-21D illustrate an exemplary single-step-assembly microstructure disposed on a substrate.

FIGS. 22A-22D illustrate another exemplary single-step-assembly microstructure disposed on a substrate.

FIGS. 23A-23C illustrate yet another exemplary single-step-assembly microstructure disposed on a substrate.

FIG. 24 illustrates an exemplary process for designing, making, and using a probe card assembly for testing electronic devices using a single-step-assembly microstructure.

FIG. 25 illustrates an exemplary semiconductor wafer with a plurality of dies.

FIG. 26 illustrates an exemplary system for testing the dies of a semiconductor wafer.

### DETAILED DESCRIPTION

The present invention relates to an assembly with a detachable member. This specification describes exemplary embodiments and applications of the invention. The invention, however, is not limited to these exemplary embodiments and applications or to the manner in which the exemplary embodiments and applications operate or are described herein.

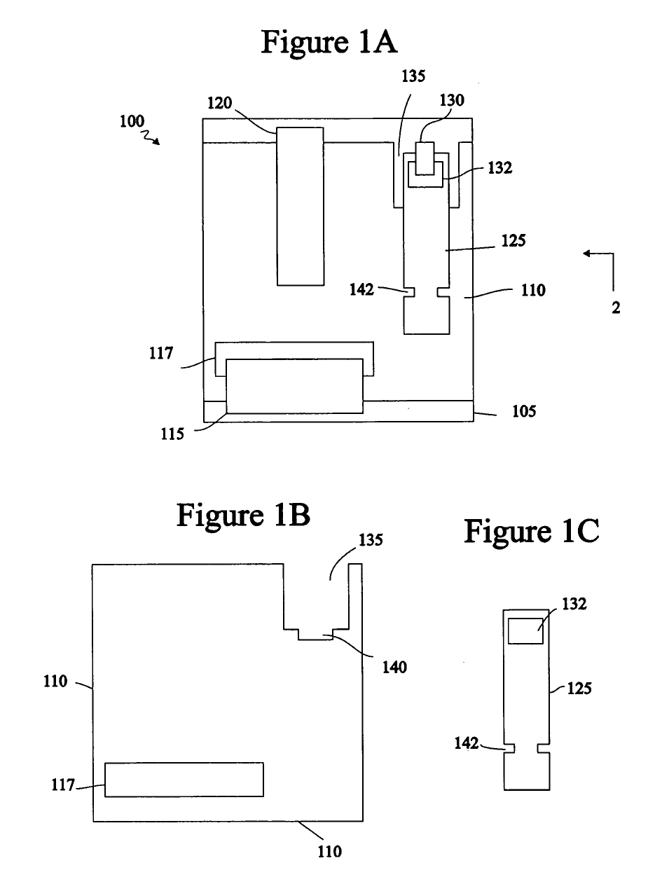

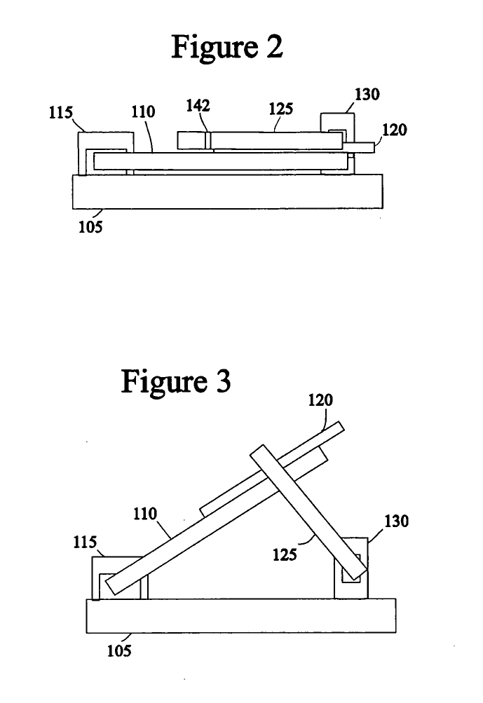

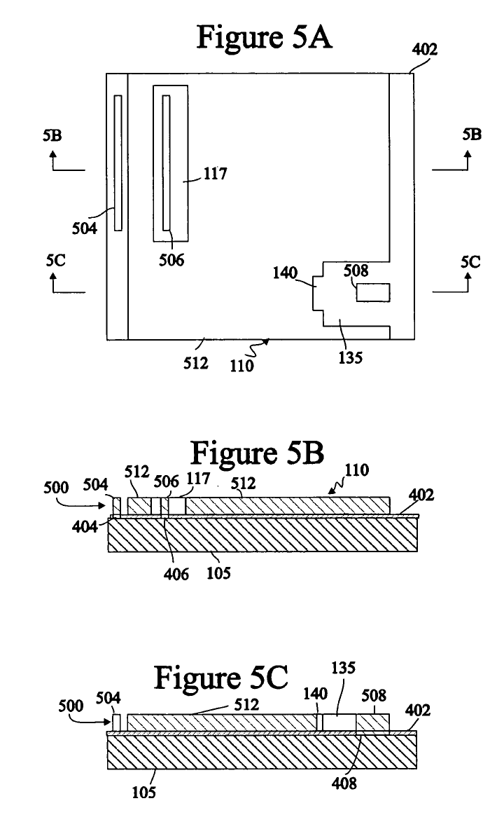

FIGS. 1A, 1B, 1C, 2, and 3 illustrate an exemplary embodiment in which a detachable member 120 is detachably secured to a single-step-assembly microstructure 100. As will be discussed in more detail below, the single-step-assembly microstructure 100 comprises a primary member 110 and a second member 125 that are configured to erect into a three-dimensional structure (as shown in FIG. 3) upon application of a single lifting force 302 to the primary member 110.

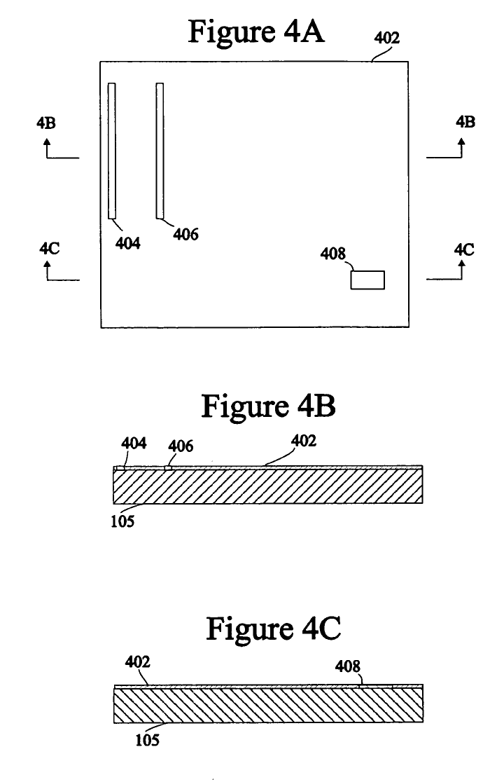

Exemplary structure 100 will now be discussed with respect to FIGS. 1A, 1B, 1C, 2, and 3. FIG. 1A shows a top view of the structure 100 before it is erected or assembled, FIG. 1B shows only the primary member 110, FIG. 1C shows only the secondary member 125, FIG. 2 shows a side view of FIG. 1A, and FIG. 3 shows the side view of FIG. 2 after the structure has been erected or assembled.

It should be noted, however, that the invention is not limited to a single-step-assembly microstructure. Rather, it will be appreciated that the teachings of present invention are applicable to other areas. For example, the teachings could be applied to a multi-step assembly structure in which the structure is assembled from two dimensions into three dimensions in multiple steps.

FIGS. 1A, 1B, 1C, 2, and 3 show an exemplary single-step-assembly microstructure 100 in accordance with one embodiment of the present invention. The assembly 100 includes a primary member 110 and a secondary member 125 disposed on a base or substrate 105. A primary hinge 115 allows primary member 110 to rotate with respect to the base 105, and secondary hinge 130 likewise allows secondary member 125 to rotate with respect to the base 105.

As shown in FIGS. 2 and 3, the primary member 110 and second member 125 are constructed such that, as the primary member 110 is lifted away from the base 105 by force 302, the primary member 110 rotates about primary hinge 115 and also causes. secondary member 125 to lift and rotate about secondary hinge 130. As this lifting and rotating continues, guiding recess 135 in primary member 110 maintains alignment between primary member 110 and secondary member 125. Eventually, locking notches 142 on secondary member 125 align with and falls into locking recess 140 in guiding recess 135, which locks primary member 110 in an assembled position as shown in FIG. 3. In this manner, the microstructure 100 may be assembled from two dimensions (as shown in FIG. 2) into three dimensions (as shown in FIG. 3) by applying a single lifting force 302 to the primary member 110.

The base 105 is a platform upon which the microstructure is manufactured and assembled. The base may be any suitable material or substrate. For example, the base may be a silicon wafer, a ceramic material, etc. The illustrated primary member 110 is a generally flat, rectangular structure that includes a guiding recess 135, a locking recess 140, and a hinge recess 117. As shown in FIGS. 1A and 1B, the guiding recess 135 is an open sided gap that, with the locking recess 140, enables the primary member 110 to be locked at a particular angle in relation to the base 105. Of course, any desired final angle of the primary member 110 with respect to the base 105 may be obtained by appropriate placement of the primary member 110, secondary member 125, locking recess 140, and locking notches 142. The primary hinge recess 117 is a closed sided internal opening in the primary member 110 that allows the primary member 110 to rotate about primary hinge 115. The primary hinge recess 117 may be made such that there is not significant lateral movement of the primary member 110 with respect to the base 105 as the primary member 110 rotates about primary hinge 115.

As shown in FIG. 2, the primary hinge 115 is coupled directly to the base 105 and a portion of the primary hinge 115 extends through the hinge recess 117 in the primary member 110. The primary hinge 115 may be any type of hinge, including without limitation a staple hinge, a scissor hinge, or a torsion bar hinge. As mentioned above, the primary hinge 115 allows the primary member 110 to rotate and also may support the primary member 110 when it is rotated into a particular angle with respect to the base 105.

As shown in FIGS. 2 and 3, it may be advantageous to dispose the detachable member such that it is offset on the upper surface of the primary member 110 on the opposite side from the hinge recess 117. This position may allow the detachable member 120 to extend above the primary member 110 when the primary member is rotated away from the base 105 (see FIG. 3). The detachable member 120 may be releasably bonded to the primary member 110 such that the detachable member 120 is readily released from the primary member 110. The detachable member 120 may be released by the use of heat, force, a chemical, etc.

The illustrated secondary member 125 may be shaped in a generally flat, rectangular configuration, and the secondary member 125 may be disposed on top of the primary member 110 as shown in FIGS. 1A and 2. The secondary member 125 includes a secondary hinge recess 132, which is an opening that facilitates rotational movement of the secondary member 125 with respect to the base 105. The secondary member 125 is narrower than the guiding recess 135 on the primary member 110. This allows the secondary member 125 to slide or scissor through the guiding recess 135 as the primary member 110 is lifted and rotates away from the base 105. As mentioned above, the locking notches 142 on the second member 125 fit into the locking recess 140 on the primary member 110, effectively locking the primary member 110 at a particular angle with respect to the base 105.

The illustrated configuration of the primary member 110 and secondary member 125 is known as a triangle style support system. Other types of support systems may be utilized and remain consistent with the present invention. For example, an orthogonal support system could be used in which a secondary member rotates orthogonally to the primary member causing the primary member 110 to be supported when it reaches a 90 degree angle of rotation from the base 105.

As best seen in FIGS. 1A and 2, a portion of the secondary hinge 130 is coupled directly to the base 105 while another portion of the secondary hinge 130 is coupled to the base 105 through the secondary hinge recess 132 of the secondary member 125. This configuration allows the secondary member 125 to rotate away from the base. The secondary member 125 may be configured to rotate without substantial lateral movement. The opposite orientation of the secondary hinge 130 with respect to the primary hinge 115 shown in FIGS. 1A, 1B, 1C, 2, and 3 allows the primary member 110 and the secondary member to rotate simultaneously away from the base 105 as a single force 302 is applied to the primary member 110.

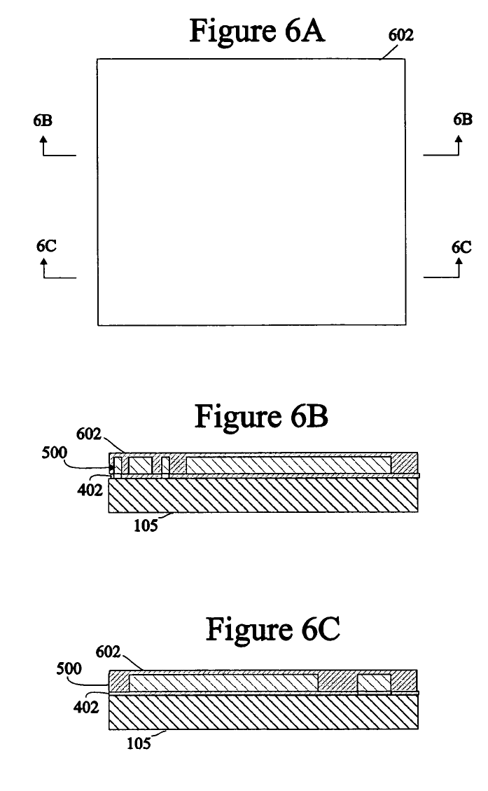

FIG. 4A through FIG. 14 illustrate an exemplary method for making the single-step-assembly microstructure 100 of FIGS. 1A, 2, and 3. As will be seen, in the exemplary method illustrated in FIGS. 4A through FIG. 14, the assembly is made layer by layer. It should be noted that many other processes could be used to manufacture the structure 100 illustrated in FIGS. 1A, 2, and 3. The illustrated process may utilize photolithographic techniques for constructing each layer.

In FIGS. 4A, 4B, and 4C (FIGS. 4B and 4C illustrate cross-sectional side views of FIG. 4A), a layer of sacrificial material 402 is deposited over a base 105 and patterned to include openings (corresponding to structural elements 404, 406, and 408). The sacrificial material 402 may be any material that can be patterned to have openings. For example, the sacrificial material 402 may be an oxide, which may be patterned by etching. As another example, the sacrificial material 402 may be a photo reactive material (e.g., a photo resist) that is patterned using photolithographic techniques.

The openings in the sacrificial layer 402 are filled with a structural material to form structural elements 404, 406, and 408. As will be seen, structural element 404 forms a portion of a first leg of the primary hinge 115; structural element 406 forms a portion of a second leg of the primary hinge 115; and structural element 408 forms a portion of a pedestal comprising part of the secondary hinge 130. The structural material that forms structural elements 404, 406, and 408 may be any type of material. For example, the structural material may be a polysilicon material, a metallic material, etc. Moreover, the structural material may be deposited using any suitable deposition method, of which many are well known to those skilled in the field.

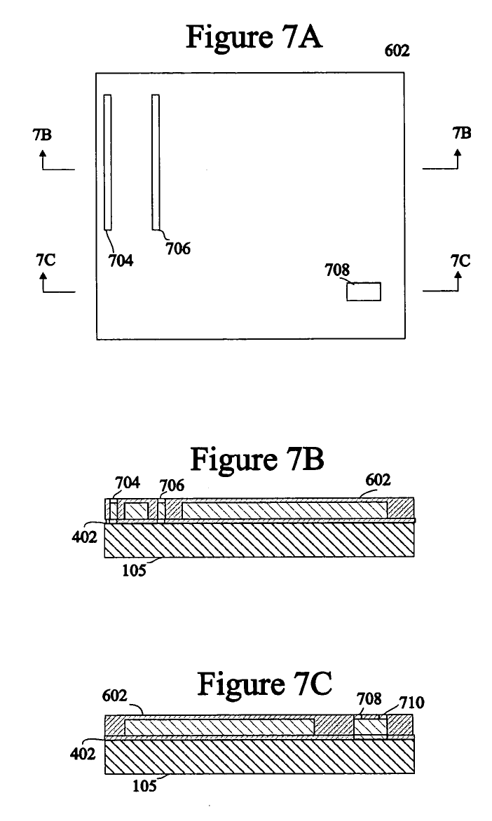

As shown in FIGS. 5A, 5B, and 5C, a layer of structural material 500 is deposited over the sacrificial material 402 and 500 patterned to define further the single-step-assembly structure. As shown, structural layer 500 is patterned to form structural elements 504, 506, 508, and 512. Structural element 504 further forms the first leg of the primary hinge 115; structural element 506 further forms the second leg of the primary hinge 115. Similarly, structural element 508 forms a portion of a pedestal of the secondary hinge 130. Structural element 512 forms the primary member 110, with hinge recess 117, guiding recess 135, and locking recess 140. Layer 500 may be deposited and patterned using any suitable process or processes. For example, the layer 500 may be deposited as a single layer and then etched to form the pattern shown in FIGS. 5A, 5B, and 5C. Alternatively, layer 500 may be deposited through a mask or into a temporary mold that defines the desired pattern.

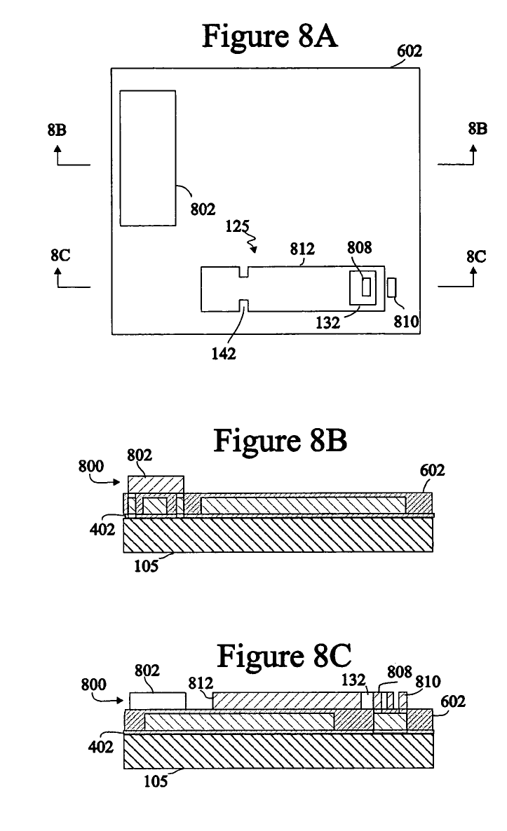

As shown in FIGS. 6A, 6B, and 6C, another layer of sacrificial material 602 is deposited over the patterned structural layer 500, filling openings in the pattern of structural layer 500. The sacrificial material 602 may be the same as sacrificial material 402 and may be deposited in the same way as sacrificial material 402.

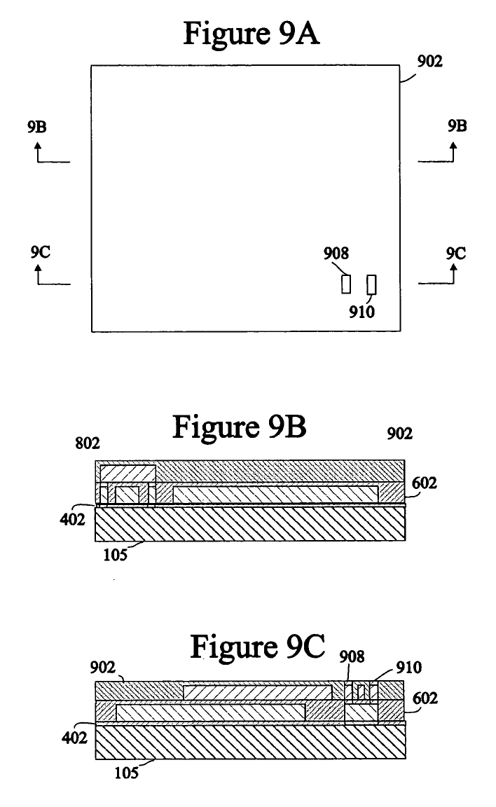

As shown in FIGS. 7A, 7B, and 7C, openings (corresponding to structural elements 704, 706, 708, and 710) are patterned in the sacrificial material 602 and filled with a structural material to form structural elements 704, 706, 708, and 710. (Sacrificial material 602 may be patterned in the same way as sacrificial material 402.) Structural element 704 further forms the first leg of the primary hinge 115; structural element 706 further forms the second leg of the primary hinge 115. Similarly, structural element 708 further forms the first leg of the secondary hinge 130, and structural element 710 further forms the second leg of the secondary hinge 130.

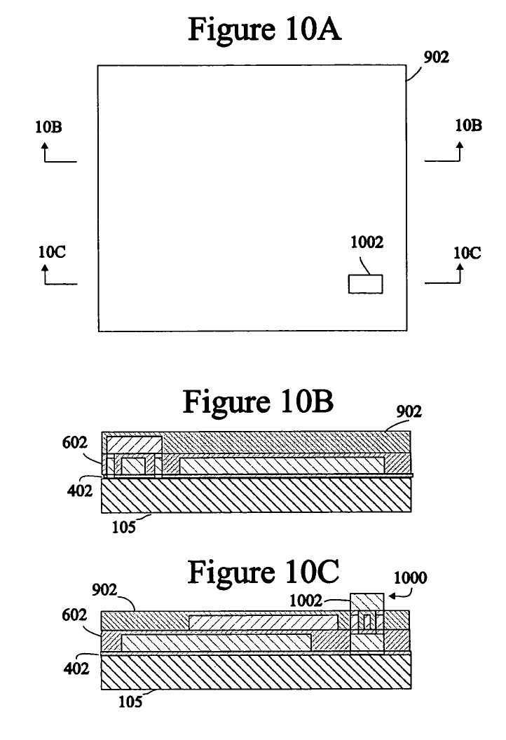

As shown in FIGS. 8A, 8B, and 8C, another layer 800 of structural material (which may be the same material as layer 500) is deposited over sacrificial material 602 and patterned to form structural elements 802, 808, 810, and 812. Structural element 802 forms the top of the primary hinge 115. Structural element 808 further forms the first leg of the secondary hinge 130, and structural element 810 further forms the second leg of the secondary hinge 130. Structural element 812 forms the secondary member 125, with secondary hinge recess 132 and locking notches 142. Layer 800 may be deposited and patterned in the same manner as layer 500.

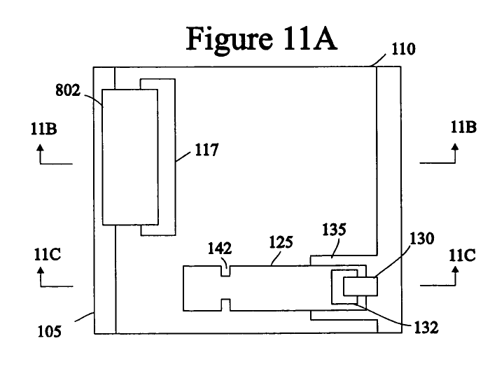

As shown in FIGS. 9A, 9B, and 9C, yet another layer of sacrificial material 902 is deposited, this time over patterned structural material layer 800. Sacrificial material 902 is also patterned to include openings that correspond to structural elements 908 and 910, which are formed by depositing structural material into the openings. Structural element 908 further forms the first leg of the secondary hinge 130, and structural element 910 further forms the second leg of the secondary hinge 130. (Sacrificial material 902 may be similar to and deposited and patterned like sacrificial material 402. Likewise, the structural material that forms elements 908 and 910 may be similar to and deposited like the structural material that forms elements 402, 404, 406, and 408.)

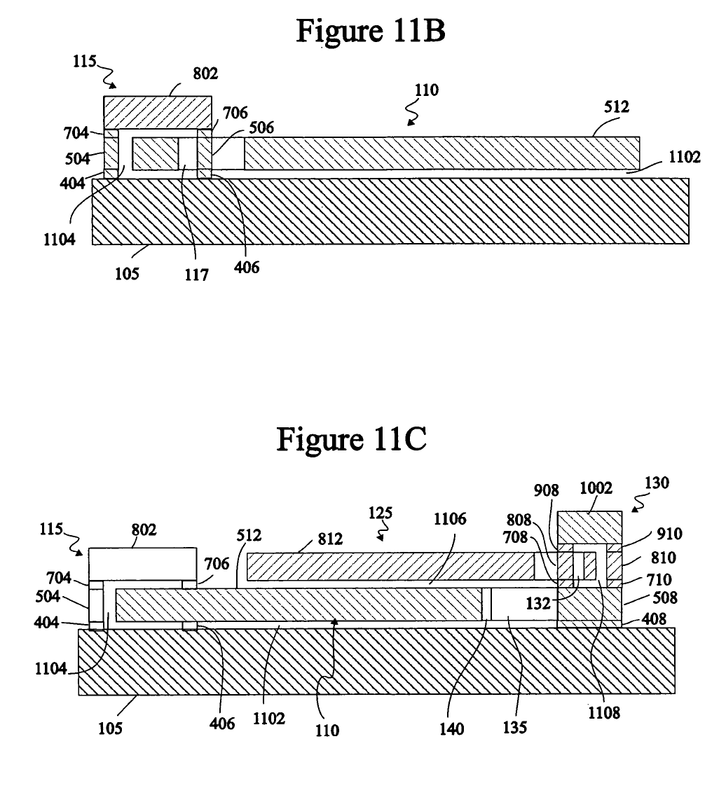

As shown in FIGS. 10A and 10C, yet another layer 1000 of structural material is deposited and patterned to form structural element 1002. (Structural layer 1000 may be the same material as structural layer 500 and may be deposited and patterned like layer 500.) Structural element 1002 forms the top of the secondary hinge 130.

It should be noted that one or more of the steps shown as being performed as distinct steps in FIGS. 4A through 10A may be combined and performed in one step. For example, FIGS. 4A-4C, on one hand, and FIGS. 5A-5C, on the other hand, need not define separate steps. For example, the openings in the sacrificial layer 402 that define structural elements 404, 406, and 408 may be filled with structural material 500 rather than in a separate deposit of structural material as described above. It should also be noted that each layer of material may be smoothed (e.g., by polishing, grinding, or lapping) before the next layer of material is deposited.) It should also be apparent that additional materials and layers may be deposited. For example, a layer of stop-etch material (not shown) may be deposited directly on the base 105 to prevent etching of the base 105. As another example, conductive seed layers may be deposited as needed to facilitate depositing of one or more of the layers of material by electroplating.

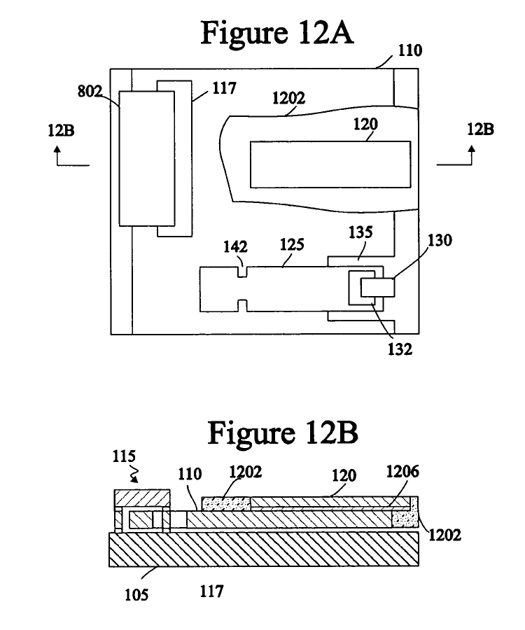

Once all of the structural layers are deposited, the sacrificial layers 402, 602, and 902 may be removed. FIGS. 11A, 11B, and 11C illustrate the structure of FIGS. 10A-10C after the sacrificial layers 402, 602, and 902 are removed. As shown, structural elements 404, 504, and 704 form a first leg of primary hinge 115, and structural elements 406, 506, and 706 form a second leg of primary hinge 115. Structural element 802 forms the top of primary hinge 115. Similarly, structural elements 408 and 508 form a pedestal comprising part of secondary hinge 130; 708, 808, and 908 form a first leg of secondary hinge 130, and structural elements 710, 810, and 910 form a second leg of secondary hinge 130. Structural element 1002 forms the top of secondary hinge 130. Primary member 110 is comprised of structural element 512 with primary hinge recess 117, locking recess 140, and guiding recess 135 as shown in FIGS. 11A-11C. Similarly, secondary member 125 is comprised of structural element 812 with secondary hinge recess 132 as also shown in FIGS. 11A-11C. Removal of the sacrificial materials 402, 602, and 902 leaves an open space 1102 between the primary member 110 and the base 105, which allows the primary member 110 to move with respect to the base. Removal of the sacrificial materials 402, 602, and 902 also leaves open space 1104 between the primary member 110 and the primary hinge 115, which allows primary member 110 to rotate about primary hinge 115. Similarly, open spaces 1106 and 1108 formed by removal of the sacrificial materials 402, 602, and 902 allow secondary member 125 to move and rotate about secondary hinge 130.

It should be apparent that the process of forming a single-step-assembly microstructure shown in FIGS. 4A through 11C is exemplary only as is the particular single-step-assembly microstructure shown in those figures. Many methods and techniques for making and assembling such microstructures are known and any such method or technique may be used. Nonlimiting examples of such techniques are disclosed in U.S. Pat. No. 6,600,850 to Fan, U.S. Pat. No. 6,567,574 to Ma et al., and Hui et al., “Single-Step Assembly Of Complex 3-D Microstructures,” Berkeley Sensor & Actuator Center (University of California, Berkley) and Intelligent Micromachine Department, Sandia National Laboratories, each of which is incorporated by reference herein in its entirety.

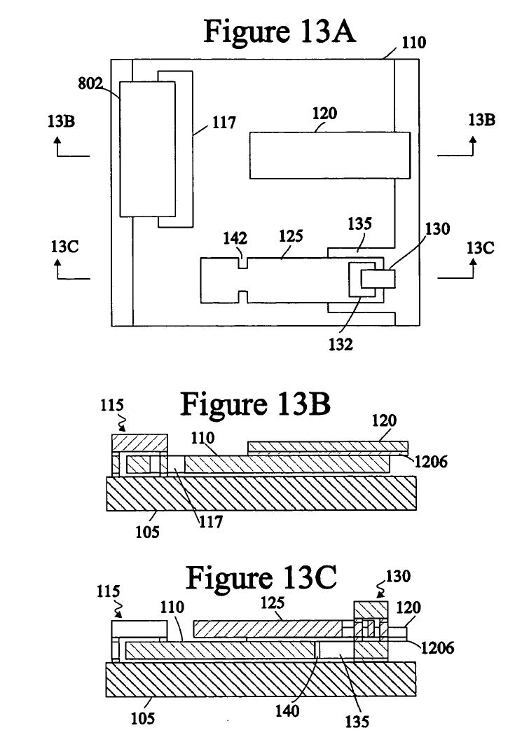

Once the microstructure assembly is fabricated as shown in FIGS. 11A, 11B, and 11C, a detachable member may be formed on or attached to the microstructure assembly. FIGS. 12A, 12B, 13A, 13B, and 13C illustrate formation of an exemplary detachable member 120 on the single-step-assembly structure. In the example shown in FIGS. 12A and 12B, a masking material 1202 is deposited on the primary member 110 and patterned to have an opening that defines the detachable member. Although FIG. 12A shows the masking material being deposited only on part of the single-step-assembly structure, the masking material 1202 may be deposited on all or any part of the single-step-assembly structure. Still referring to FIGS. 12A and 12B, a layer of release material 1206 is deposited in the opening of the masking material 1202, after which material defining the detachable member 120 is deposited over the release material 1206.

The masking material may be any material that can be patterned. For example, photo reactive materials (e.g., photo resists) may be used. The release material may be any material that is readily removed, releasing the detachable member from the primary member 110. For example, the release layer may be aluminum, which is readily dissolved with sodium hydroxide. Other examples of a release layer include without limitation copper, gold, titanium-tungsten, and a polymer. The material deposited to form the detachable member 120 may be any material and may depend on the type of detachable member being made and on its intended use. For example, if the detachable member is to be a probe for probing an electronic device during testing of the electronic device, the detachable member may comprise an electrically conductive material (e.g., palladium, gold, rhodium, nickel, cobalt, silver, platinum, conductive nitrides, conductive carbides, tungsten, titanium, molybdenum, rhenium, indium, osmium, copper, refractory metals, or alloys of any of the foregoing). The material that forms the detachable member 120 may be deposited using any suitable method including without limitation electroplating, chemical vapor deposition, physical vapor deposition, sputter deposition, electroless plating, electron beam deposition, and thermal evaporation. As shown in FIGS. 13A, 13B, and 13C, the masking material 1202 is removed.

It should be noted that the detachable member 120 shown in FIGS. 12A through 13C is exemplary only. For example, the detachable member 120 may be made in any of a variety of shapes. U.S. Published Patent Application 2003/0199179 to Dozier et al., U.S. Published Patent Application 2001/0002341 to Eldridge et al., and U.S. patent application No. 09/032,473, filed Feb. 26, 1998, to Pedersen et al. (each of which is incorporated herein by reference in its entirety) disclose examples of spring contacts or probes formed in a variety of shapes, and the detachable member 120 may be in any such shape. As another example, the detachable member 120 may be formed in multiple steps and may comprise multiple parts. U.S. Pat. No. 6,520,778 to Eldridge et al. and U.S. Pat. No. 6,255,126 to Mathieu et al. (each of which is incorporated herein by reference in its entirety) illustrate examples of multipart spring contacts or probes that may be formed or formed separately and then attached to primary member 110 as detachable member 120. The detachable member 120 need not be formed lithographically. For example, the detachable member 120 may comprise a wire bonded to the primary member 110, and the wire may be over coated. Examples of such wire-based detachable members are described in U.S. Pat. No. 5,476,211 to Khandros, U.S. Pat. No. 5,917,707 to Khandros et al., and U.S. Pat. No. 6,336,269 to Eldridge et al. (each of which is incorporated herein by reference in its entirety).

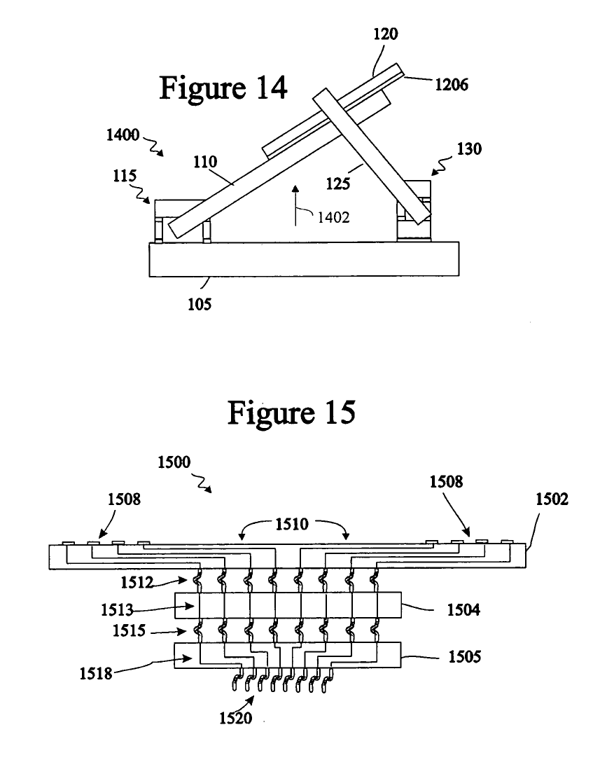

FIG. 14 shows a side view of the single-step-assembly structure 1400 (which was fabricated in a flat, two-dimensional orientation in FIGS. 4A through 13C) lifted into an assembled position, which is similar to FIG. 3 discussed above. (Note that structure 1400 may be the same as or similar to structure 100 in FIG. 1A.) That is, a single force 1402 applied to the primary member 110 and directed away from the base 105 lifts the primary member 110 and causes the primary member 110 to rotate about primary hinge 115. Force 1402 may be applied manually, for example using a probe needle and micro-manipulator assembly to lift the primary member 110. Alternatively, a machine may be configured to lift automatically primary member 110. As primary member 110 rotates, the primary member 110 lifts secondary member 125, causing secondary member 125 to rotate about hinge 130. Locking notches 142 and locking recess 140 engage and lock the assembly structure 1400 into an assembled position, as shown in FIG. 14.

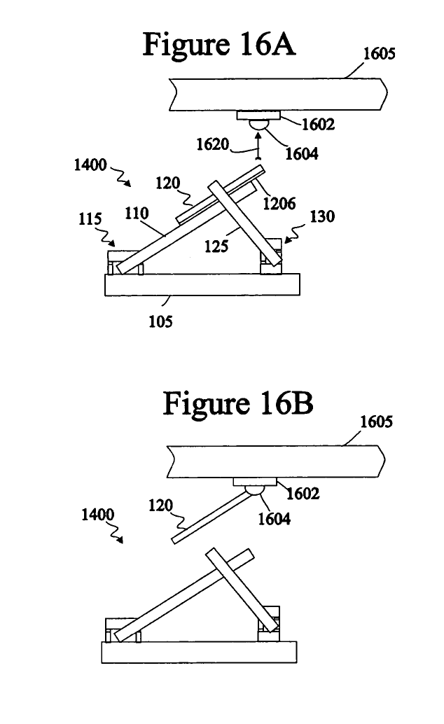

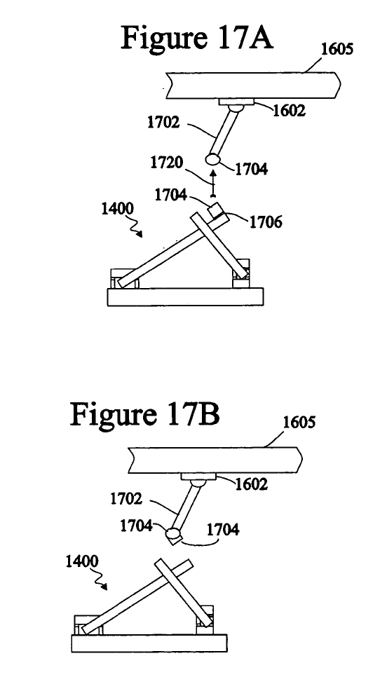

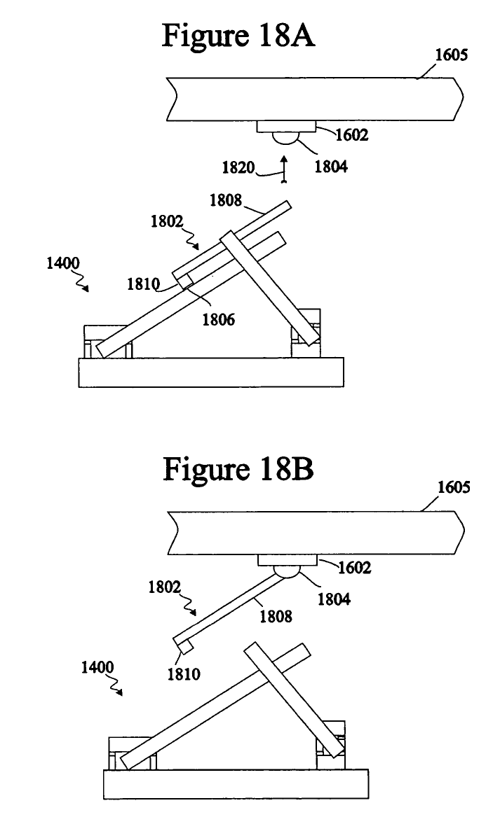

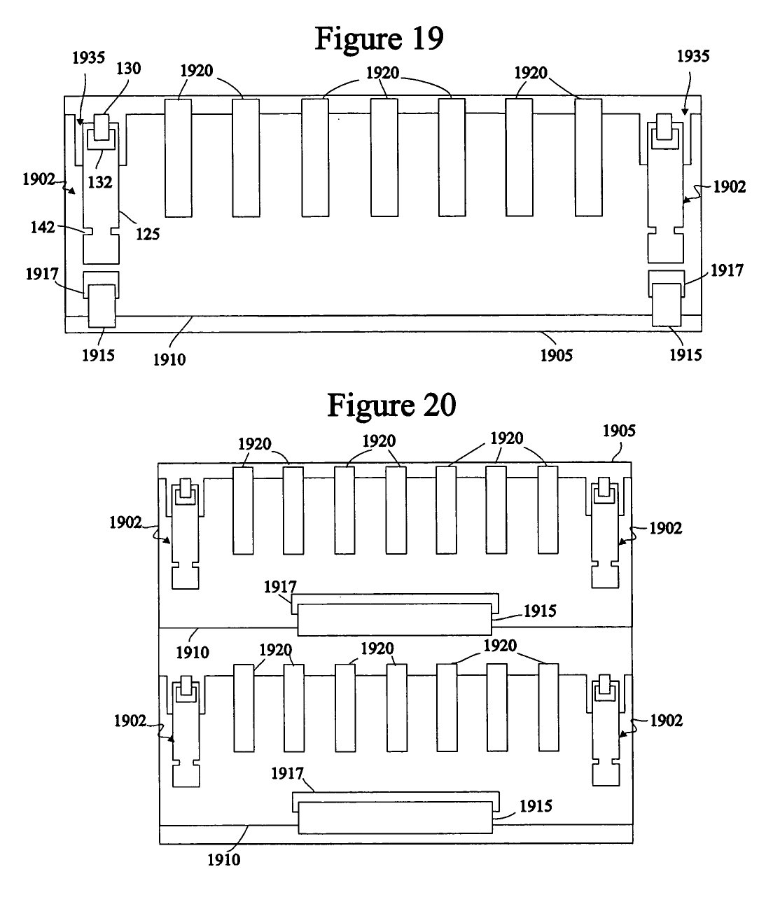

FIGS. 15, 16A, and 16B illustrate an exemplary use of the single-step-assembly structure 1400 shown in FIG. 14 to form probes for a probe card apparatus. FIGS. 17A and 17B and FIGS. 18A and 18B illustrate exemplary alternative detachable members.

FIG. 15 illustrates an exemplary probe card assembly 1500 for interfacing a tester (not shown) to an electronic device to be tested (not shown). Terminals 1508 interface to the tester (not shown), and probes 1520 contact the electronic device to be tested (not shown). Electrical connections 1510 through a printed circuit board 1502, conductive spring contacts 1512, electrical connections 1513 through interposer 1504, conductive spring contacts 1515 and electrical connections 1518 through probe substrate 1505 electrically connect the tester interface terminals 1508 with the probes 1520. (A more detailed description of such a probe card assembly may be found in U.S. Pat. No. 5,974,662 to Eldridge et al., which is incorporated in its entirety herein by reference.) Such a probe card assembly 1500 may be used to test semiconductor dies, and the process discussed herein of making a single-step-assembly structure with a detachable member may be used to form part or all of probes 1520.

FIG. 16A illustrates a portion of a probe substrate 1605 and one terminal 1602 on the probe substrate. Probe substrate 1605 may be similar to probe substrate 1505 and may be implemented in a probe card assembly such as probe card assembly 1500. As shown in FIG. 16A, the single-step-assembly structure 1400, in its erected position, is located such that the detachable member 120 is moved 1620 into contact with solder 1604 on a terminal 1602 of the probe substrate 1605. As shown in FIG. 16B, the release material 1206 is removed, which releases the detachable member 120 from the primary member 110. The solder 1604 may be reflowed before or after releasing the detachable member 120 from the primary member 110. The detachable member thus becomes one of the probes (e.g., like 1520 of FIG. 15) attached to probe substrate 1605. Structure 1400 may be discarded. It should be noted that the detachable member 120 may be attached to the terminal 1602 by other than solder. For example, brazing, welding, adhesives, etc. may be used.

FIGS. 17A and 17B illustrate an alternative detachable member 1704 that is to be a tip of a probe 1702. As shown in FIG. 17A, the single-step-assembly structure 1400 is positioned such that the detachable member 1704 is moved 1720 into contact with solder 1704 on a probe 1702 that is attached to a terminal 1602 of the probe substrate 1605. As shown in FIG. 16B, the release material 1706 is removed, which releases the detachable member 1704 from the primary member 110. The detachable member 1704 thus becomes the tip of probe 1702. Detachable member 1704 may be made in the same way that detachable member 120 is made.

FIGS. 18A and 18B illustrate yet another detachable member 1802 that comprises a beam 1808 and a tip 1810. Detachable member 1802 may be manufactured in two patterned masking layers (similar to masking layer 1202): the first layer patterned to define the tip 1810, and the second layer patterned to define the beam 1808. (U.S. Pat. No. 6,255,126, which is incorporated herein by reference in its entirety, describes techniques for making similar multipart probes or spring contacts). As shown in FIG. 18A, the single-step-assembly structure 1400 is positioned such that the detachable member 1802 is moved 1820 into contact with solder 1804 on a terminal 1602 of the probe substrate 1605. As shown in FIG. 16B, the release material 1806 is removed, which releases the detachable member 1802 from the primary member 110. The solder 1804 may be reflowed before or after releasing the detachable member 1802 from the primary member 110. The detachable member 1802 thus becomes one of the probes (e.g., like 1520 of FIG. 15) attached to probe substrate 1605.

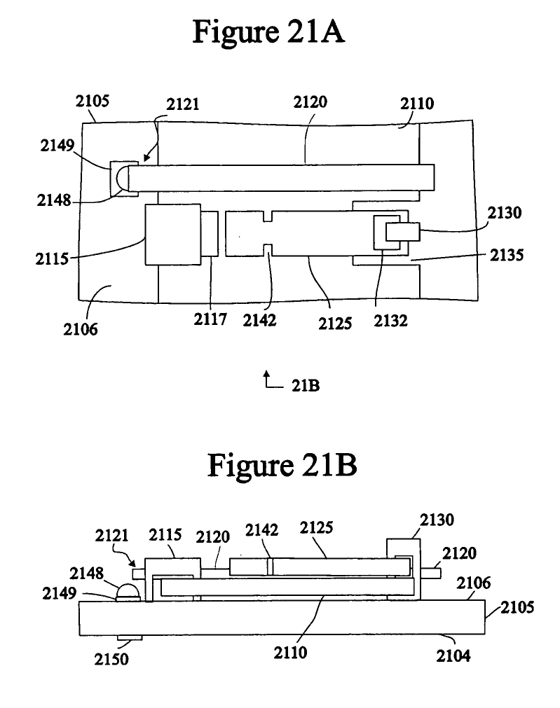

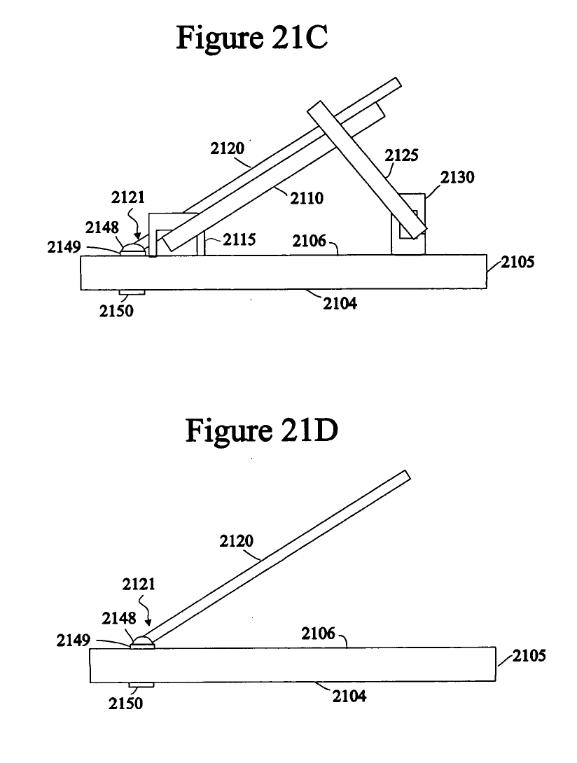

FIGS. 19 and 20 illustrate single-step-assembly structures on which a plurality of detachable members are formed.

FIG. 19 includes a primary member 1910 with primary hinge recesses 1917 that rotate about primary hinges 1915 and two secondary members 1902. Primary member 1910, hinge recesses 1917, and primary hinges 1915 may be similar to primary member 110, primary hinge recess 117, and primary hinge 115 discussed above. Each secondary member may be similar to secondary member 125 discussed above and include a member 125 with a secondary hinge recess 132 that rotates about a secondary hinge 130. Like primary member 110, primary member 1910 rotates about hinges 1915 as it is lifted, which also lifts and guides each secondary member 1902 through guiding recesses 1935 until locking notches 142 in secondary members 1902 lock with locking recesses (not shown in FIG. 19 but similar to 140 in FIG. 1B) in guiding recesses 1935 (which may be similar to guiding recess 135 discussed above). As shown in FIG. 19, a row of detachable members 1920 is formed on primary member 1910. In this way, a row of detachable members 1920 may be formed, raised into position by lifting the primary member 1910 until it locks with secondary members 1902, attaching the detachable members 1920 to another entity (e.g., a probe substrate), and releasing the detachable members 1920 from the primary member 1910, all as generally illustrated in FIGS. 4A though 18B above. For example, the detachable members 1920 may be probes (e.g., 120 or 1802) or probe tips (e.g., 1704) and may be attached to a plurality of terminals of a probe substrate as generally shown in FIGS. 16A through 18A. In this manner, a row of probes may be attached to a row of terminals on a probe substrate.

FIG. 20 illustrates the use of two primary members 1910, each or which may be like primary member 1910 of FIG. 19 and each of which functions with two corresponding secondary members 1902, as in FIG. 19, on a base 1905. In this way, an array of detachable members 1920 may be made and attached to another device (e.g., a probe substrate) as generally illustrated in FIGS. 4A through 18B above. Again, the detachable members 1920 may be probes (e.g., 120 or 1802) or probe tips (e.g., 1704) and may be attached to a plurality of terminals of a probe substrate as generally shown in FIGS. 16A through 18A. In this manner, an array of probes may be attached to an array of terminals on a probe substrate.

The uses and applications illustrated and discussed with regard to FIGS. 15 through 20 in which the detachable member is a probe (e.g., 120 or 1802) or a probe tip (e.g., 1704) or a plurality of probes or probe tips (see FIGS. 19 and 20) that are attached to a probe card assembly are exemplary only. Use of the present invention is not limited to a probe card assembly or even to probing applications. For example, the present invention may be used to create probes for any type of probing device, including without limitation any device for probing an electronic device (e.g., packaged or unpacked semiconductor dies). Other non-probing examples include without limitation micro-mirrors, micro-antennae, photosensitive structures, pixel display structures, phosphor dots, or any type of microelectromechanical system (MEMS). Moreover, use of the present invention is not limited to a single-step-assembly structure but may include a structure that is assembled in multiple steps.

An array of probes, like array 1520 (which may be a two-dimensional array), may thus be made one probe at a time by making one probe on one single-step-assembly structure (e.g., similar to structure 1400 in FIGS. 16A through 18B), attaching the one probe to probe substrate 1505, and repeating until a desired array of probes 1520 is made. Alternatively, an array of probes may be made by making one probe on each of a plurality of single-step-assembly structures (e.g., similar to structure 1400), attaching those probes to probe substrate 1505, and repeating as necessary until a desired array of probes 1520 is made. (Of course, if sufficient single-step-assemblies are used, the array may be made without the need to repeat.) As yet another alternative, an array of probes may be made by making a plurality of probes on one single-step-assembly structure (e.g., as shown in FIG. 19), attaching those probes to probe substrate 1505, and repeating as necessary until a desired array of probes 1520 is made. As still another alternative, an array of probes may be made by making a plurality of probes on a plurality of single-step-assembly structures (e.g., as shown in FIG. 20), attaching those probes to probe substrate 1505, and repeating as necessary until a desired array of probes 1520 is made.

It should also be noted that the substrate (e.g., 1505, 1605) to which the detachable members or probes are attached need not be a single substrate. For example, the substrate to which the detachable members are attached may be a plurality of tiles each attached or designed to be attached to a larger substrate. An example in which a plurality of tiles with attached probes are themselves attached to a larger substrate is shown in U.S. Pat. No. 5,806,181, which is incorporated in its entirety herein by reference. In FIG. 6A of U.S. Pat. No. 5,806,181 a tile 600 with attached probes is shown, and such tiles are attachable to areas 624a, 624b, 624c, and 624d on larger substrate 622. U.S. Pat. No. 5,806,181 shows another example in FIG. 9A in which a plurality of smaller substrates 902 with attached probes are themselves attached to a larger substrate 904.

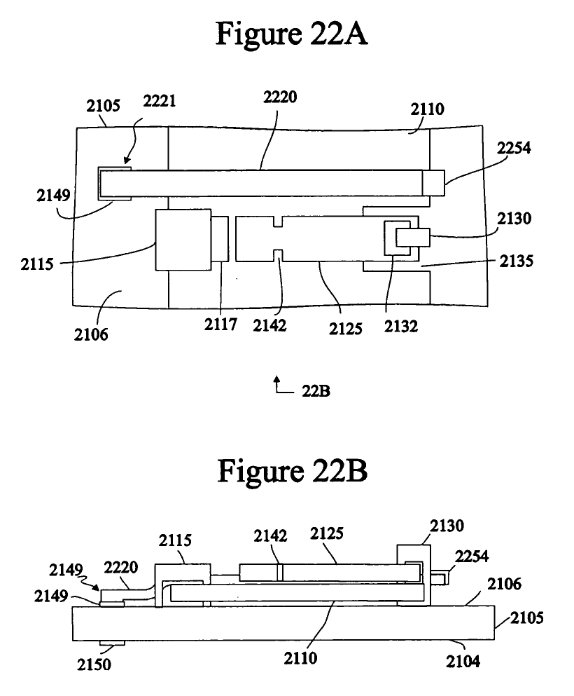

FIGS. 21A through 21D illustrate yet another exemplary use of a single-step-assembly microstructure with a detachable member 2120. FIG. 21A illustrates a top view and FIG. 21B illustrates a side view of a single-step-assembly microstructure with a detachable member 2120 disposed on the substrate 2105 to which the detachable member 2120 is to be attached. The single-step-assembly microstructure illustrated in FIGS. 21A and 21B may be generally similar to any of the single-step-assembly microstructures illustrated in FIGS. 1 through 20. The single-step-assembly microstructure shown in FIGS. 21A and 21B includes primary member 2110 having a primary hinge recess 2117 that is rotatable about a primary hinge 2115 and a secondary member 2125 having a secondary hinge recess 2132 that is rotatable about a secondary hinge 2130. The primary member 2110, primary hinge 2115, secondary member 2125, and secondary hinge 2130 may be like and function similar to like named elements illustrated in FIGS. 1-20 and discussed above. That is, as the primary member 2110 is lifted away from substrate 2105, the secondary member 2125 also moves away from substrate 2105 guided by guiding recess 2135 until notches 2142 in the secondary member 2125 engage a locking recess (not shown) in the guiding recess 2135. (The locking recess in the guiding recess 2135 is hidden from view in FIGS. 21A and 21B but may be generally similar to locking recess 140 shown in FIG. 1.)

The exemplary substrate 2105 illustrated in FIGS. 21A and 21B includes a pair of electrically conductive terminals 2149 and 2150 disposed on opposite surfaces 2106 and 2104 of the substrate 2105. A conductive via (not shown) through the substrate 2105 may electrically connect the terminals 2149 and 2150. As shown in FIGS. 21A, 21B, and 21C, an end portion 2121 of the detachable member 2120 (which may be made of one or more electrically conductive materials) is positioned adjacent terminal 2149 so that the end portion 2121 of the detachable member 2120 engages the terminal 2149 while the single-step-assembly microstructure is in an assembled position (as shown in FIG. 21C). Solder 2148 or other conductive adhesive material (e.g., a brazing material) may secure the end 2121 of the detachable member 2120 to the terminal 2149.

As shown in FIG. 21D, once the solder 2148 has sufficiently hardened to hold the detachable member 2120 in place, the single-step-assembly microstructure may be removed. Although not shown in FIGS. 21A through 21D, a layer of a release material (not shown) may be disposed between the elements of the single-step-assembly microstructure and the surface 2106 of the substrate 2105 to facilitate removal of the single-step-assembly microstructure from the substrate 2105. For example, the release layer (not shown) may be any material that is readily etched away or otherwise removed. A similar release layer (not shown) may be disposed between the detachable member 2120 and the primary member 2110 to facilitate removal of the detachable member 2120 from the primary member 2110.

In FIGS. 21A through 21D, substrate 2105 is shown in partial view only. Substrate 2105 may include a plurality of terminals 2149 on surface 2106 each of which is electrically connected to a terminal 2150 on the opposite surface 2104. Alternatively, terminals 2149 may be connected via traces (not shown) to other terminals (not shown) or electronic components (not shown) on surface 2106. As yet another alternative, terminal pairs 2149 and 2150 on opposite surfaces 2106 and 2104 of substrate 2105 may be offset one from another, effecting a space transformation function (or fanning in or out) of the terminals (e.g., 2150) on one surface (e.g., 2104) as compared to the terminals (e.g., 2149) on the other surface (e.g., 2106). Such a space transformation is shown in probe substrate 1505 of FIG. 15.

Substrate 2105 may be a probe substrate like probe substrate 1505 of FIG. 15, and a plurality of detachable members 2120 may be attached to substrate 2105 as probes like probes 1520 in FIG. 15. In addition, a plurality of detachable members 2120 may be attached en mass to substrate 2105 as generally illustrated in FIGS. 19 and 20.

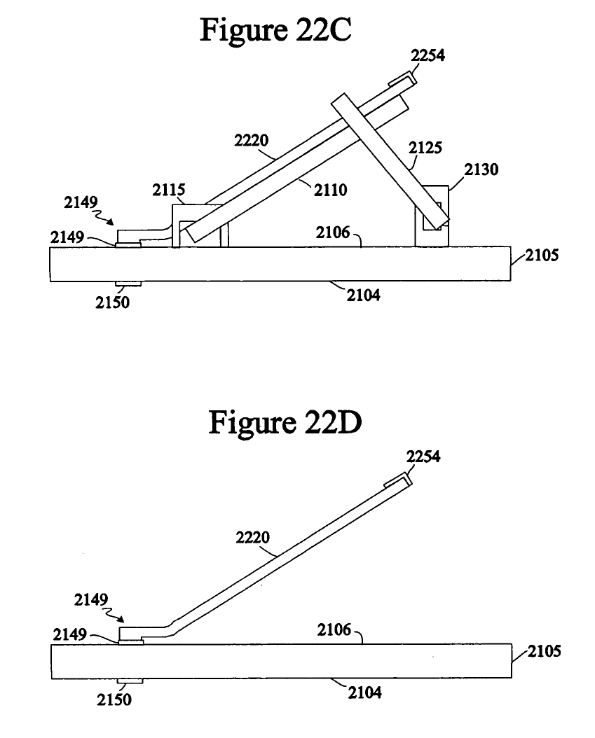

FIGS. 22A through 22D illustrate an exemplary single-step-assembly microstructure that is generally similar to the single-step-assembly microstructure shown in FIGS. 21A through 21D. In FIGS. 22A through 22D, however, the detachable member 2220 is formed of a material that is initially flexible. An end portion 2221 of the detachable member 2220 is attached to terminal 2149 upon formation of the detachable member 2220 or by soldering, brazing, or otherwise securing the end portion 2221 to the terminal 2149. Because the detachable member 2220 is flexible, the detachable member 2220 readily flexes as the single-step-assembly microstructure is lifted into an assembled position (shown in FIG. 22C). The detachable member 2220 is then cured (e.g., by heat treatment, chemical treatment, etc.) and hardened. Once the detachable member 2220 is cured and hardened, the single-step-assembly microstructure may be removed as shown in FIG. 22D and as discussed above with respect to FIGS. 21A through 21D.

As shown in FIGS. 22A through 22D, detachable member 2220 may include a contact tip 2254, which may be formed of one or more materials (e.g., palladium-cobalt) with properties advantageous for making electrical or other contact with another device. (Other exemplary tip materials include palladium, gold, rhodium, nickel, cobalt, silver, platinum, conductive nitrides, conductive carbides, tungsten, titanium, molybdenum, rhenium, indium, osmium, copper, refractory metals, or alloys of any of the foregoing.) Materials suitable for forming the detachable member include nickel, cobalt, palladium, platinum, and their alloys. Organic materials, such as pre-cast or b-staged materials may also be used. (Organic materials may be made conductive by mixing such materials with metallic or conducting powders.) It should be noted that, although cured and hardened to maintain its shape and position, detachable member 2220 in FIG. 22D may nevertheless provide a desired level of compliance, flexibility, and/or resilience as, for example, an electrically conductive probe. As discussed above with respect to FIGS. 21A through 21D, a plurality of detachable members 2220 may be attached en mass to substrate 2105 as generally illustrated in FIGS. 19 and 20.

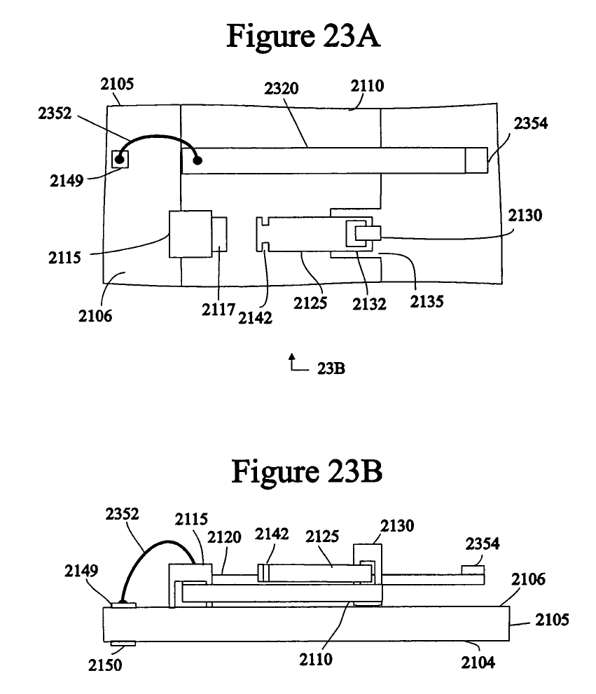

The single-step-assembly microstructure shown in FIGS. 23A through 23C is also generally similar to the single-step-assembly microstructure shown in FIGS. 21A through 21D. Detachable member 2320 is, however, electrically connected to terminal 2149 by a bonded wire 2352 or other electrically conductive connector. For example, wire 2352 may alternatively be a flexible metal foil or other flexible electrical connection. Wire 2352 may be bonded to the detachable member 2320 and the terminal 2149 using standard wire bonding techniques. As shown in FIG. 23C, once assembled into an erected position, the single-step-assembly microstructure is not removed but remains as a support for the detachable member 2320, which as shown, includes a contact tip 2354 that may be made of any of the materials mentioned above with regard to tip 2254. Detachable member 2320 in FIGS. 23A through 23C is not truly detachable but is so named to be consistent with the naming conventions throughout this specification.

As discussed above with regard to FIGS. 21A through 21D, a plurality of detachable members 2320 may be formed on one or more primary members 2110 (e.g., as shown in FIG. 19 and/or FIG. 20). In such a case, each detachable member 2320 may be flexible and/or resilient and thereby provide individualized (or local) compliance (i.e., the compliance in one probe is generally independent of compliance in the other probes) when brought into contact with another device. In addition, the primary member 2110 and/or the secondary member 2125 may also be flexible and/or resilient and thereby provide a global level of compliance for a plurality of the detachable members 2320.

It should be apparent that the embodiments shown in FIGS. 21A through 23C are exemplary only and configurations in one embodiment may be utilized in another embodiment. For example, the single-step-assembly microstructure may be left in place (as in the embodiment shown in FIGS. 23A through 23C) in the embodiments shown in FIGS. 21A through 22D rather than removing the microstructure. Similarly, the single-step-assembly microstructure shown in FIGS. 23A through 23C may be removed as is shown in the embodiments of FIGS. 21A through 22D.

As another example, the detachable member 2120 and 2220 in the embodiments shown in FIGS. 21A through 22D may be configured as shown in FIGS. 23A through 23C and electrically connected to terminal 2149 by a wire (e.g., like wire 2352 of FIGS. 23A through 23C) or other similar electrical connector. Similarly, the detachable members 2120 and 2320 in the embodiments shown in FIGS. 21A through 21D and 23A through 23C may be formed and connected to terminal 2149 like detachable member 2220 in FIGS. 22A through 22D. Likewise, the detachable members 2220 and 2320 in the embodiments shown in FIGS. 22A through 23C may be soldered or otherwise attached to terminal 2149 like detachable member 2120 in FIGS. 21A through 21D.

As yet another example, any of the detachable members 2120, 2220, and 2320 may include tips, including without limitation the exemplary contact tips 2254 and 2354 shown in FIGS. 22A through 23C.

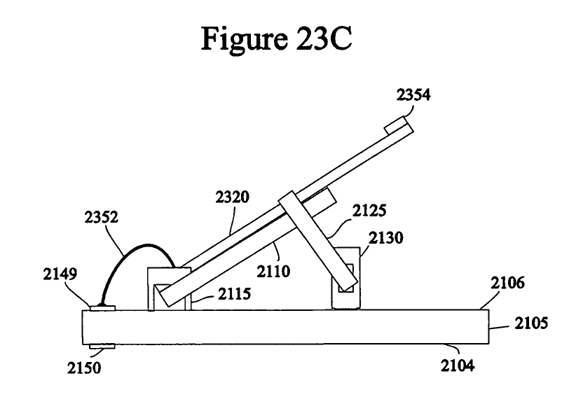

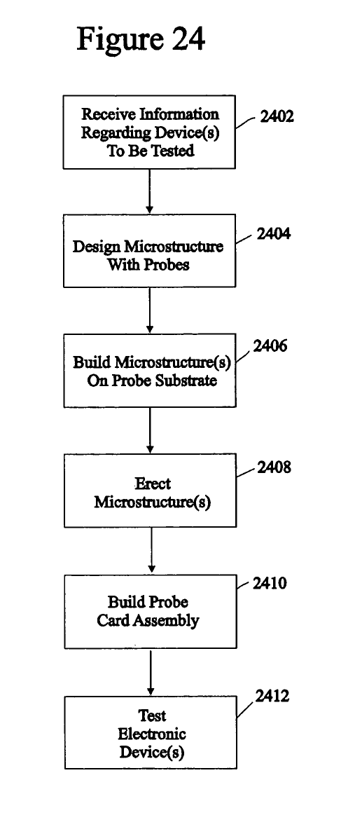

FIG. 24 illustrates an exemplary process in which the single-step-assembly microstructures described herein are used in making a probe card assembly for testing an electronic device. At step 2402, information regarding the electronic device is received. Such information may include the locations of test points on the electronic device and the type of signals input into or output from the electronic device at each test point. FIG. 25 illustrates an example in which the electronic device to be tested is one or more dies 2504 of a semiconductor wafer 2502. Each die 2504 shown in FIG. 25 includes a row of bond pads 2506 through which signals are input to or output from the die 2504. The information received at step 2402 for dies 2504 would include, among other possible information, the locations of each pad in a row 2506 on a die 2504 and the type of signal input to or output from each pad.

At step 2404, one or more single-step-assembly microstructures similar to any of the microstructures illustrated herein are designed to, when erected, configure probes attached to the microstructures into an array for contacting one or more rows 2506 of bond pads on one or more dies 2504 of the wafer 2502. For example, a single-step-assembly microstructure similar to the microstructure shown in FIG. 19 may be designed for each die 2504 to be tested during one test run of dies 2504 on wafer 2502. (As is known, depending on the number of dies that can be tested simultaneously, multiple test runs may be needed to test all of the dies 2504 on a wafer 2402.) In such a case, the microstructure would include a number of probes equal to the number of bond pads in a bond pad row 2506. At step 2406, the single-step-assembly microstructure or microstructures are made on a probe substrate, which may be similar to substrate 2105 shown in FIGS. 21A through 23C. At step 2408, the single-step-assembly microstructure or microstructures are erected and the probes are attached to the probe substrate. The microstructure or microstructures may be made and erected and the probes attached to the probe substrate using any of the techniques described herein (in which the probes are the detachable members). For example, the microstructure or microstructures may be made and erected and the probes attached to the probe substrate using any of the techniques shown in FIGS. 21A through 23C. The probe substrate may be like substrate 1505 in probe card assembly 1500 shown in FIG. 15.

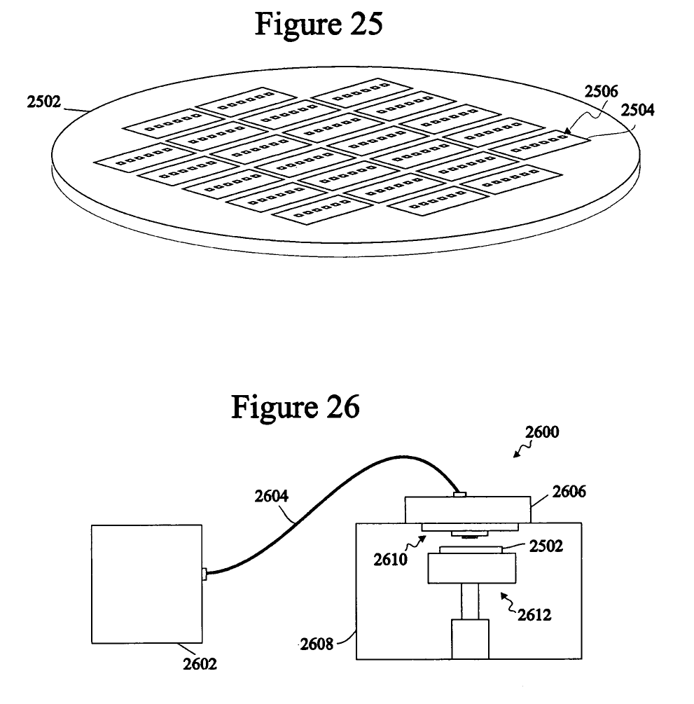

At step 2410, the probe substrate along with the probes that are now attached to the probe substrate are integrated into a probe card assembly. For example, the probe substrate may be integrated as element 1505 into a probe card assembly similar to the probe card assembly shown in FIG. 15. At step 2412, the probe card assembly is used to test one or more electronic devices. FIG. 26 illustrates an exemplary system 2600 that may be used to test dies 2504 of the semiconductor wafer 2502 of FIG. 25. As is generally known, a probe card assembly 2610 (designed and made as described above) is secured in a prober 2608, and the wafer 2502 whose dies 2504 are to be tested is secured to a moveable chuck 2612 in the prober 2608. The chuck 2612 then moves the wafer such that bond pads 2506 of one or more dies 2504 are brought into contact with the probes of probe card assembly 2610. A tester 2602 (which may be a computer) then generates test data that is communicated through communications link 2604 to a probe head 2606 and through probe card assembly 2610 to the dies 2504 in contact with the probes of the probe card assembly 2610. Output data generated by the dies 2504 is communicated in reverse direction back to the tester 2602, which evaluates the response data to determine whether the dies pass or fail the testing. Dies 2504 that pass the testing are singulated and may then be packaged and subjected to further testing. Dies 2504 that pass all of the testing are then sold.

The described embodiments are to be considered in all respects only as illustrative and not restrictive. The scope of the invention is, therefore, indicated by the appended claims rather than by the foregoing description.

What is claimed is:

1. An assembly comprising:
a base;
a first member rotatably coupled to the base; and
a detachable member releasably coupled to the first member, wherein the detachable member is configured to be coupled to a device.

2. The assembly of claim 1, wherein the base is a silicon substrate.

3. The assembly of claim 1, wherein the base is a silicon wafer.

4. The assembly of claim 1, wherein the first member may rotate away from the base.

5. The assembly of claim 1 further comprising a first hinge coupled to the base, and wherein the first hinge rotatably couples the first member to the base.

6. The assembly of claim 5 wherein the first hinge comprises multiple polysilicon layers.

7. The assembly of claim 5, wherein the first member comprises a hinge recess configured to interact with the first hinge to allow for rotational movement of the first member.

8. The assembly of claim 5, wherein the first hinge and the first member are fabricated using photolithography techniques.

9. The assembly of claim 5 further comprising a second hinge and a second member, wherein the second member is rotatably coupled to the second hinge.

10. The assembly of claim 9, wherein application of a single force to the first member causes rotation of the first member about the first hinge and rotation of the second member about the second hinge erecting the assembly into an erected configuration.

11. The assembly of claim 1, wherein the assembly further includes a support member, and wherein the support member and first member are interconnected such that when the first member is rotated away from the base, the support member also rotates away from the base.

12. The assembly of claim 11, wherein application of a single force to the first member causes rotation of the first member and rotation of the support member erecting the assembly into an erected configuration.

13. The assembly of claim 1, wherein the assembly further includes a support member, and wherein when the first member is rotated away from the base at a particular angle, the support member locks the first member at the particular angle.

14. The assembly of claim 1, wherein the detachable member is coupled to the first member such that it rises above the first member when the assembly is erected.

15. The assembly of claim 1, wherein the detachable member is a probe configured for use with a probe card.

16. The assembly of claim 15, wherein the probe includes a beam and a tip.

17. The assembly of claim 1, wherein the detachable member is a tip for a probe.

18. The assembly of claim 1, wherein the detachable member is offset from the first member to which it is coupled.

19. The assembly of claim 1 further comprising a plurality of the detachable members, each releasably coupled to the first member.

20. The assembly of claim 1, wherein the device comprises the base, and the detachable member is configured to be coupled to the device after the first member is rotated into an erected position.

21. The assembly of claim 1, wherein the device is independent of the assembly.
